(19) United States
(12) Patent Application Publication
(10) Pub. No.: US 2026/0088840 A1
(43) Pub. Date: Mar. 26, 2026

(54) DYNAMIC ADAPTIVE BIASING FOR AMPLIFICATION CIRCUITRY

(71) Applicant: QUALCOMM Incorporated, San Diego, CA (US)

(72) Inventors: Andre ISIDORO PRATA, Nijmegen (NL); Islam EL BAKOURY, Shrewsbury, MA (US); Jiri STULEMEIJER, Heerlen (NL); Ryan Scott Castro SPRING, San Diego, CA (US); Intae KANG, San Diego, CA (US); Antonino SCUDERI, San Diego, CA (US)

(21) Appl. No.: 18/892,911

(22) Filed: Sep. 23, 2024

(51) Int. Cl. H04B 1/04; H03F 3/24

(52) U.S. Cl. CPC H04B 1/0475; H03F 3/245; H03F 2200/451; H04B 2001/0425

(57) ABSTRACT

Certain aspects of the present disclosure provide techniques and circuitry for signal amplification for transmission. One example method generally includes: amplifying a signal via at least one amplifier, performing a first adjustment of at least one bias current for the at least one amplifier, identifying a performance indicator associated with the at least one amplifier after performing the first adjustment of the at least one bias current, and performing a second adjustment of the bias current for the at least one amplifier based on the performance indicator.

### BACKGROUND

### Field of the Disclosure

Certain aspects of the present disclosure generally relate to electronic components and, more particularly, to circuitry for signal amplification.

### Description of Related Art

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system). Wireless devices may include transmitters for processing signals for transmission via antennas. A transmitter may include one or more amplifiers for signal amplification for transmissions.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards a method for signal amplification. The method generally includes: amplifying a signal via at least one amplifier, performing a first adjustment of at least one bias current for the at least one amplifier, identifying a performance indicator associated with the at least one amplifier after performing the first adjustment of the at least one bias current, and performing a second adjustment of the bias current for the at least one amplifier based on the performance indicator.

Certain aspects of the present disclosure are directed towards an apparatus for signal amplification. The apparatus generally includes at least one amplifier amplifying a signal and a controller coupled to the amplifier and configured to: cause a first adjustment of at least one bias current for the at least one amplifier, identify a performance indicator associated with the at least one amplifier after performing the first adjustment of the at least one bias current, and cause a second adjustment of the bias current for the at least one amplifier based on the performance indicator.

Certain aspects of the present disclosure are directed towards a non-transitory computer-readable medium having instructions stored thereon, that when executed by one or more processors, cause the one or more processors to: cause a first adjustment of at least one bias current for at least one amplifier, identify a performance indicator associated with the at least one amplifier after performing the first adjustment of the at least one bias current, and cause a second adjustment of the bias current for the at least one amplifier based on the performance indicator.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver front end, in accordance with certain aspects of the present disclosure.

FIG. 4 illustrates an example electronic device including a power amplifier (PA) implemented with digital predistortion (DPD) circuitry, in accordance with certain aspects of the present disclosure.

FIG. 5 is a flow diagram illustrating example operations for bias current reduction during mission mode, in accordance with certain aspects of the present disclosure.

FIG. 6 is a graph illustrating an impact of adjusting a bias current to a performance indicator, in accordance with certain aspects of the present disclosure.

FIG. 7 illustrates amplification circuitry including a driver amplifier (DA) and a power amplifier (PA), in accordance with certain aspects of the present disclosure.

FIG. 8 is a flow diagram illustrating example operations for signal amplification, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to techniques and apparatus for dynamic biasing of an amplifier (e.g., for signal transmission). For example, some aspects are directed towards adjusting the bias current of a power amplifier for a particular power supply setting during an online calibration procedure (e.g., during mission mode). The bias current adjustment may be performed in increments (e.g., steps), where after each increment, a feedback receiver may be used to determine (e.g., calculate or sense) one or more key performance indicators (KPIs). The bias current may be decreased until one or more thresholds per specifications associated with the one or more KPIs are no longer being met, as described in more detail herein. Decreasing the bias current may result in reduced power consumption. In some cases, the bias current may be increased. For instance, extra margin may be provided for a specific KPI by increasing the bias current of the PA, albeit at the cost of reduced power amplifier efficiency (PAE).

### Example Wireless Communications

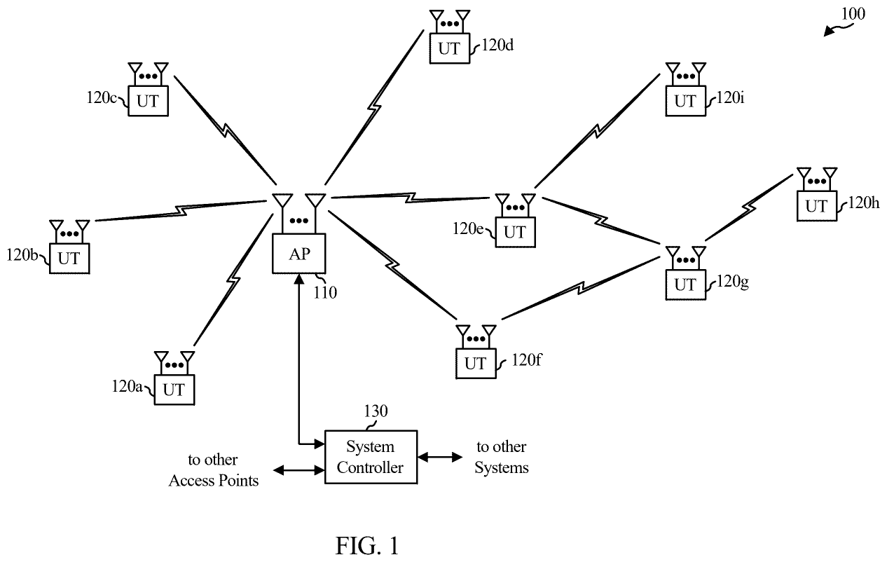

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported). In some aspects, the user terminal 120 or access point 110 may include an amplifier that may be implemented with dynamic bias current adjustment, as described in more detail herein.

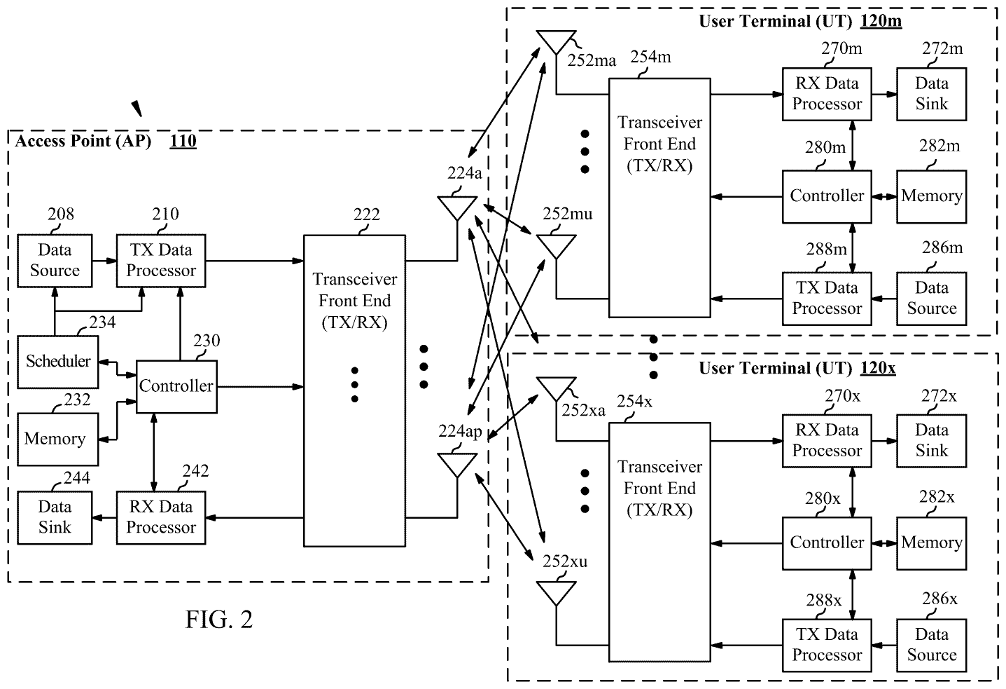

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a transmitter (TX) data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. A receiver (RX) data processor 242 processes (e.g., demodulates, deinterleaves, and decodes) the recovered uplink data symbol stream in accordance with the rate used for that stream to obtain decoded data. The decoded data for each user terminal may be provided to a data sink 244 (e.g., corresponding to data sink 272 of UT) for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal. In some aspects, the transceiver front end 254 or 222 may include an amplifier that may be implemented with dynamic bias current adjustment, as described in more detail herein.

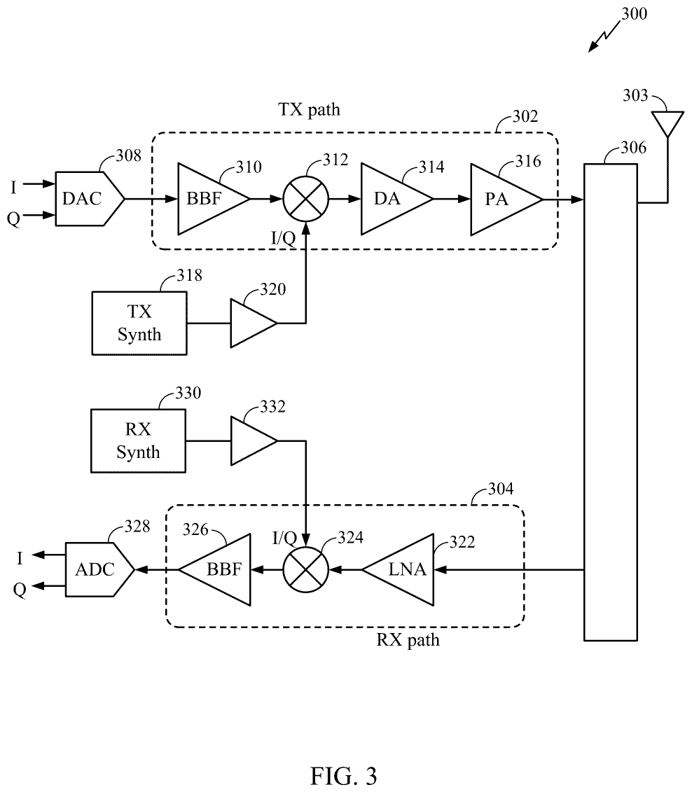

FIG. 3 is a block diagram of an example transceiver front end 300, such as transceiver front ends 222, 254 in FIG. 2, in which aspects of the present disclosure may be practiced. The transceiver front end 300 includes at least one transmit (TX) path 302 (also known as a transmit chain) for transmitting signals via one or more antennas and at least one receive (RX) path 304 (also known as a receive chain) for receiving signals via the one or more antennas. When the TX path 302 and the RX path 304 share an antenna 303, the paths may be connected with the antenna via an interface 306, which may include any of various suitable RF devices, such as a switch, a duplexer, a diplexer, a multiplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, the DA 314, and the PA 316 may be included in a radio frequency integrated circuit (RFIC). In some cases, the PA 316 may be external to the RFIC. In some cases, the DA 314 may include a pre-DA that may drive a DA, where the DA drives the PA 316.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies of the LO frequency and the frequencies of the baseband signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303. While one mixer 312 is illustrated, several mixers may be used to upconvert the filtered baseband signals to one or more intermediate frequencies and to thereafter upconvert the intermediate frequency (IF) signals to a frequency for transmission. In some aspects, the DA 314 and/or the PA 316 may be implemented with dynamic bias current adjustment, as described in more detail herein.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (e.g., downconvert). The baseband signals output by the mixer 324 may be filtered by the BBF 326 before being converted by an analog-to-digital converter (ADC) 328 to digital I and/or Q signals for digital signal processing.

Certain transceivers may employ a variable-frequency oscillator (e.g., a voltage-controlled oscillator (VCO) or a digitally controlled oscillator (DCO)) to generate a stable, tunable LO signal with a particular tuning range. Thus, the transmit LO signal may be produced by a TX frequency synthesizer 318, which may be buffered or amplified by amplifier 320 before being mixed with the baseband signals in the mixer 312. Similarly, the receive LO signal may be produced by an RX frequency synthesizer 330, which may be buffered or amplified by amplifier 332 before being mixed with the RF signals in the mixer 324. For certain aspects, a single frequency synthesizer may be used for both the TX path 302 and the RX path 304. In certain aspects, the TX frequency synthesizer 318 and/or RX frequency synthesizer 330 may include a frequency multiplier, such as a frequency doubler, that is driven by an oscillator (e.g., a VCO) in the frequency synthesizer.

While FIGS. 1-3 provide wireless communications as an example application in which certain aspects of the present disclosure may be implemented to facilitate understanding, certain aspects described herein may be used for amplification in any of various other suitable systems (e.g., an audio system, a high-speed serializer/deserializer (SerDes) system, a video system, radio over fiber system, or other electronic system).

### Example Techniques for Biasing Amplification Circuitry

Cellular-related equipment (e.g., phones, tablets, or wearables) may use a radio frequency (RF) power amplifier (PA) (e.g., PA 316) for signal amplification before transmission. Some aspects of the present disclosure are directed towards an online mechanism to adjust the bias current of the PA and increase PA efficiency (PAE) without compromising linearity specifications, allowing energy consumption to be decreased. The bias current (referred to herein as “Icq”) may set the PA operation point and class of operation. Lowering the bias current of the PA increases the PAE, but may also increase the non-linear behavior of the PA. In some cases, digital pre-distortion (DPD) circuitry may be used to distort the input signal of the PA to increase the effective PA linearity.

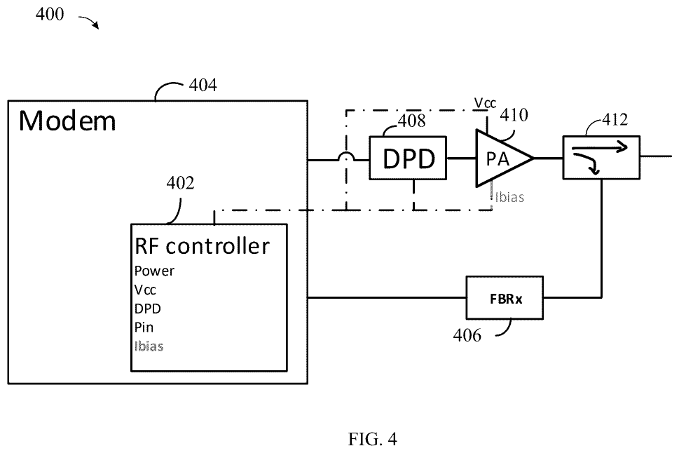

FIG. 4 illustrates an example electronic device 400, in accordance with certain aspects of the present disclosure. The electronic device 400 may include a PA 410 (e.g., corresponding to the PA 316 of FIG. 3). A DPD circuit 408 may be coupled to an input of the PA 410 as shown. In some cases, the DPD circuit 408 may be part of the modem 404, or may be implemented external to the modem 404 as shown. The output of the PA 410 may be (selectively) coupled to a feedback receiver 406 (labeled “FBRx”), via a directional coupler 412, for example. The feedback receiver 406 may be used to feed back an output signal of the PA 410 to a modem 404 (e.g., after signal processing, such as downconverting, filtering, and digitally converting) for determination (e.g., computation) of one or more key performance indicators (KPIs) such as an adjacent channel leakage ratio (ACLR), error vector magnitude (EVM), emissions, and/or sensitivity. The modem 404 may include an RF controller 402 (e.g., corresponding to controller 230 or 280 of FIG. 2) that may be used to control one or more configurations associated with the PA. For example, via the dashed control lines, controller 402 may adjust a supply voltage (Vcc) for the PA, adjust an amplification power (e.g., gain) of the PA, adjust a distortion associated with the DPD circuit 408, regulate an input signal power (Pin) for the PA, and/or adjust a bias current (Ibias, also referred to herein as “Icq”) for the PA.

The DPD circuit 408 may be used to set the PA operation at a certain target compression. For example, the input signal to the PA may be distorted while Vcc is adjusted (e.g., reduced) to operate the PA at a target compression point. In some aspects, between each DPD estimation and distortion adjustment, the bias current of the PA may be lowered in small steps until a bias current threshold (e.g., limit) is reached. The change of the bias current in each step may be small such that the degradation in linearity (e.g., before DPD adjustment) is minor. The bias current adjustment may be performed during mission mode (e.g., during wireless transmissions). Therefore, the bias current adjustment may be performed in small steps to avoid degradation of KPIs beyond thresholds set by specification (or at least the amount by which one or more KPIs may be degraded beyond thresholds set by specification is reduced). By reducing the bias current, the PAE may be increased while also changing the non-linear behavior of the PA each time the bias current is reduced. In some aspects, before the bias current is adjusted, the DPD may be re-estimated to provide improved linearity.

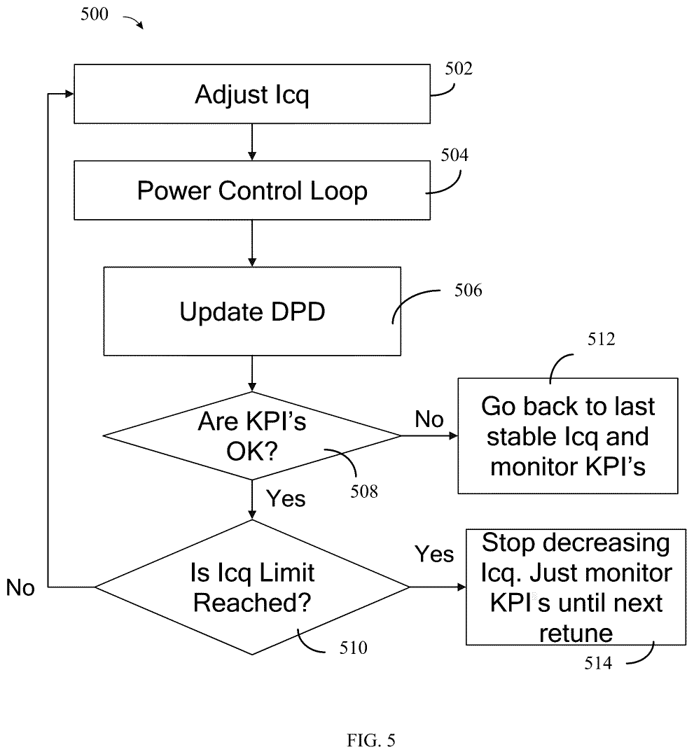

FIG. 5 is a flow diagram illustrating example operations 500 for bias current adjustment during mission mode, in accordance with certain aspects of the present disclosure. The operations 500 may be performed by a controller such as the controller 402 of FIG. 4.

The operations 500 may be performed after Vcc reduction is performed to operate the PA at target compression. Bias current adjustment may be performed for a specific Vcc set to operate the PA at target compression. For example, at block 502, the controller adjusts a bias current (Icq) by a predetermined amount. As described in more detail herein, the amount by which to adjust the bias current may be determined using a precharacterization of the PA (e.g., characterization of the PA in a lab to determine PA response to changes in bias current). At block 504, the controller operates a power control loop to regulate the power of the PA. For example, the modem 404 may receive a feedback signal from the feedback receiver 406, based on which the one or more KPIs may be determined (e.g., calculated). At block 506, the controller may optionally perform a DPD update. In other words, based on the feedback signal, the controller may adjust the configuration of the DPD circuit 408 to improve the one or more KPIs (e.g., increase the effective linearity of the PA 410). At block 508, the controller determines (e.g., based on the feedback signal from the feedback receiver 406) whether the one or more KPIs meet thresholds set by specifications. If not, at block 512, the controller may adjust the bias current of the PA back to a previous bias current setting known to meet the KPI thresholds and continue to monitor the KPIs. If the controller determines at block 508 that the one or more KPIs meet the thresholds after adjusting the bias current, the controller, at block 510, determines whether a bias current (Icq) lower threshold (e.g., limit) has been reached. If so, at block 514, the bias current may no longer be decreased, and the controller may continue to monitor the KPIs until a subsequent retuning is performed for the amplifier (e.g., until a subsequent Vcc adjustment). If not, the controller may perform the bias current adjustment again at block 502 and repeat the operations 500 until one or more KPIs no longer meet respective thresholds or the bias current lower threshold has been met.

The bias current lower threshold (e.g., Icq limit) may be determined in any suitable manner such as by PA precharacterization to identify a lower limit for PA operations. In some aspects, the bias current limit may correspond to a predetermined KPI. For example, the bias current may be reduced until a KPI such as ACLR reaches some lower ACLR threshold. Similarly, the step size for adjusting the bias current at block 502 may be determined using precharacterization of the PA. For example, the impact of a particular adjustment to the bias current on the PA non-linearity or KPIs may be determined, and the bias current adjustment step may be selected such that the impact on the PA non-linearity or KPIs is not too large to avoid overly degrading the KPIs beyond thresholds.

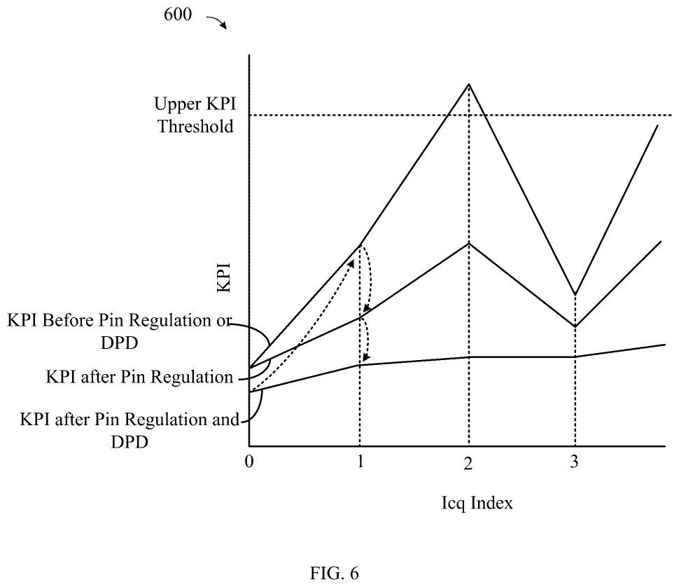

FIG. 6 is a graph 600 illustrating the impact to KPI (e.g., ACLR) from adjustments in bias current, in accordance with certain aspects of the present disclosure. Different bias current levels may be predetermined and associated with indices (e.g., Icq indices 0-3 as shown). The bias current for the PA may be set to a first bias current level associated with an Icq index 0. As shown, the PA bias current may be adjusted (e.g., decreased) to Icq index 1, causing the KPI to increase as shown. In some cases, the KPI may be improved (e.g., reduced) by performing Pin regulation and reduced again by adjusting the DPD configuration as shown. The PA bias current may be adjusted (e.g., reduced) again to Icq index 2 causing another KPI increase, followed by Pin regulation and DPD configuration adjustment to improve (e.g., decrease) the KPI. This process may be repeated until a KPI threshold (e.g., an upper KPI threshold) cannot be met (e.g., even with Pin regulation and DPD configuration adjustment) or until the bias current threshold (e.g., a lower bias current limit) is met as described herein. As shown, when transitioning from Icq index 1 to Icq index 2, the KPI may increase above an upper KPI threshold. Thus, before Pin regulation is performed to improve the KPI below the upper KPI threshold, the threshold per specifications may not be met. The amount of time during which the KPI is above the upper KPI threshold may be short, and the level by which the KPI is above the upper KPI threshold may be small. Therefore, not meeting the KPI threshold by the small amount or short duration of time may be acceptable during mission mode. As described, using PA precharacterization, the amount that Icq may be adjusted at each step may be selected so that the KPI is not degraded to an unacceptable level above a respective threshold per specifications.

While the example bias current adjustment techniques provided herein have been described to decrease the bias current to save power, certain aspects of the present disclosure may be applied to increase the bias current of a PA. For example, extra margin for a specific KPI may be provided by increasing the bias current of the PA, albeit at the cost of reduced PAE. The bias current of the PA may be increased during mission mode until a specific target KPI is reached or until a predetermined upper bias current threshold (e.g., limit) is reached.

In some aspects, parameters for performing the bias current adjustment may be saved in memory (e.g., memory 232 or memory 282 of FIG. 2). For example, the KPI thresholds per specifications may be saved in memory. In some aspects, the starting point for Icq may be saved in memory. In some aspects, the step size for adjusting the bias current (e.g., the amount by which the bias current is adjusted at each step) may be saved in memory. In some aspects, an upper and/or a lower threshold (e.g., limit) for Icq may be saved in memory.

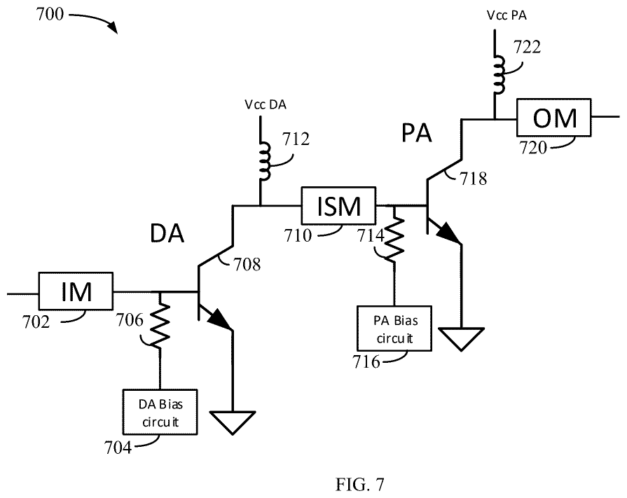

FIG. 7 illustrates amplification circuitry 700 including a DA and a PA, in accordance with certain aspects of the present disclosure. As shown, the amplification circuitry 700 may include a transistor 708 used to implement a DA such as the DA 314 of FIG. 3 and a transistor 718 used to implement a PA such as the PA 316 of FIG. 3 or the PA 410 of FIG. 4. An input matching (IM) circuit 702 may be coupled to a base of transistor 708. As shown, a DA bias circuit 704 may be used to provide a DA bias current to the base of transistor 708 through a resistive element 706. As described herein, a controller such as the controller 402 of FIG. 4 may cause the DA bias current to be adjusted by controlling the DA bias circuit 704. The emitter of transistor 708 may be coupled to a reference potential node, and a collector of transistor 708 may be coupled to a voltage rail (labeled “VCC DA”) for the DA through an inductive element 712, for example.

An intermediate stage matching circuit 710 (labeled “ISM”) may be coupled between the collector of transistor 708 and a base of transistor 718. A PA bias circuit 716 may be used to provide a PA bias current to the base of transistor 718 through a resistive element 714, for example. As described herein, a controller such as the controller 402 of FIG. 4 may cause the PA bias current to be adjusted by controlling the PA bias circuit 716. The collector of transistor 718 may be coupled to an output matching circuit 720 (labeled “OM”) and to a PA voltage rail (labeled “Vcc PA”) through an inductive element 722, for example. In some aspects, the controller may adjust the bias current for the PA and DA by different amounts as determined using a precharacterization of the PA and DA. For example, the PA response to changes in bias current may be precharacterized together with or separately from the DA.

Typical amplification circuits provide a fixed bias current for an amplifier for a certain power range (e.g., for a certain range of Vcc). Certain aspects of the present disclosure provide for dynamic adjustment of bias current during online operations (e.g., mission mode) using a feedback receiver to identify an impact of bias current adjustment to one or more KPIs. In this manner, the energy consumption of the amplifier may be decreased, resulting in decreased energy consumption for an electronic device. Some aspects of the present disclosure are directed towards dynamically improving margins for KPIs and adapting to more stringent emission specifications by adjusting a bias current for an amplifier. Certain aspects allow for a bias current of an electronic device to be adjusted dynamically for different scenarios such as different environment temperatures or scenarios that demand more stringent or less stringent KPIs. The dynamic adjustment of bias current also reduces memory consumption of an electronic device as preconfigured bias current settings may not have to be predetermined and saved for an amplifier of the electronic device.

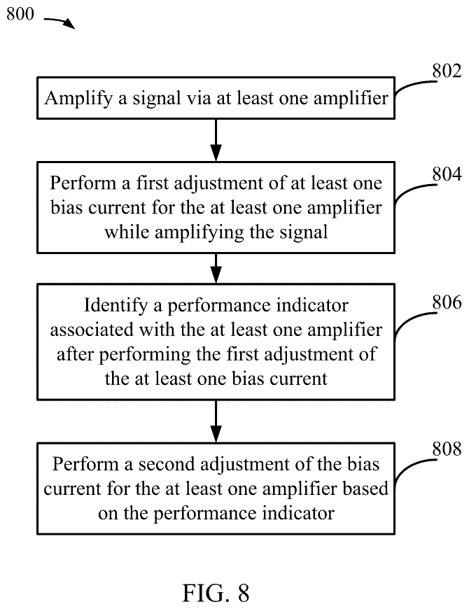

FIG. 8 is a flow diagram illustrating example operations 800 for signal amplification, in accordance with certain aspects of the present disclosure. The operations 800 may be performed, for example, by an electronic device such as the electronic device 400 of FIG. 4.

At block 802, the electronic device amplifies a signal via at least one amplifier (e.g., a DA such as the DA 314 and/or PA such as PA 316 or PA 410). At block 804, the electronic device may perform a first adjustment (e.g., by controlling DA bias circuit 704 and/or PA bias circuit 716) of at least one bias current for the at least one amplifier. In some aspects, the first adjustment is performed while the at least one amplifier is operating in mission mode (e.g., while the signal is being amplified). Performing the first adjustment of the at least one bias current may include decreasing the bias current for the at least one amplifier. In some aspects, performing the first adjustment of the at least one bias current may include increasing the bias current for the at least one amplifier.

At block 806, the electronic device may identify a performance indicator (e.g., a KPI such as ACLR) associated with the at least one amplifier after performing the first adjustment of the at least one bias current. At block 808, the electronic device may perform a second adjustment of the bias current for the at least one amplifier based on the performance indicator.

In some aspects, the second adjustment may be performed based on the performance indicator meeting a performance indicator threshold. For example, performing the first adjustment may include decreasing the at least one bias current for the at least one amplifier, and performing the second adjustment may include further decreasing the bias current for the at least one amplifier based on the performance indicator meeting the performance indicator threshold.

In some aspects, the second adjustment may include setting the bias current to at least one predetermined bias current level (e.g., a previous stable Icq as described with respect to block 512 of FIG. 5) based on the performance indicator not meeting a performance indicator threshold. The at least one predetermined bias current level may be determined to result in the performance indicator meeting the performance indicator threshold.

In some aspects, the electronic device may perform one or more configuration adjustments associated with the at least one amplifier after performing the first adjustment of the at least one bias current. The performance indicator may be identified after performing the one or more configuration adjustments. For example, performing the one or more configuration adjustments may include at least one of adjusting a digital predistortion of the signal to be amplified or adjusting an input power associated with the signal to be amplified.

In some aspects, the electronic device may detect whether the at least one bias current after performing the first adjustment has reached at least one bias current threshold. The second adjustment of the bias current may be performed based on the detection.

In some aspects, the at least one amplifier may include at least one of a pre-DA, a DA, or a PA. The at least one bias current may include at least one of a first bias current for the pre-DA, a second bias current for the DA, or a third bias current for the PA.

### EXAMPLE ASPECTS

Aspect 1: A method for signal amplification, comprising: amplifying a signal via at least one amplifier; performing a first adjustment of at least one bias current for the at least one amplifier; identifying a performance indicator associated with the at least one amplifier after performing the first adjustment of the at least one bias current; and performing a second adjustment of the bias current for the at least one amplifier based on the performance indicator.

Aspect 2: The method of Aspect 1, wherein the first adjustment is performed while the at least one amplifier is operating in mission mode.

Aspect 3: The method of Aspect 1 or 2, wherein performing the first adjustment of the at least one bias current comprises decreasing the bias current for the at least one amplifier.

Aspect 4: The method according to any of Aspects 1-3, wherein the second adjustment is performed based on the performance indicator meeting a performance indicator threshold.

Aspect 5: The method of Aspect 4, wherein performing the first adjustment comprises decreasing the at least one bias current for the at least one amplifier, and wherein performing the second adjustment comprises further decreasing the bias current for the at least one amplifier based on the performance indicator meeting the performance indicator threshold.

Aspect 6: The method according to any of Aspects 1-5, wherein performing the second adjustment comprises setting the bias current to at least one predetermined bias current level based on the performance indicator not meeting a performance indicator threshold.

Aspect 7: The method of Aspect 6, wherein the at least one predetermined bias current level is determined to result in the performance indicator meeting the performance indicator threshold.

Aspect 8: The method according to any of Aspects 1-7, further comprising performing one or more configuration adjustments associated with the at least one amplifier after performing the first adjustment of the at least one bias current, wherein the performance indicator is identified after performing the one or more configuration adjustments.

Aspect 9: The method of Aspect 8, wherein performing the one or more configuration adjustments includes at least one of adjusting a digital predistortion of the signal to be amplified or adjusting an input power associated with the signal to be amplified.

Aspect 10: The method according to any of Aspects 1-9, further comprising detecting whether the at least one bias current after performing the first adjustment has reached at least one bias current threshold, wherein the second adjustment of the bias current is performed based on the detection.

Aspect 11: The method according to any of Aspects 1-10, wherein the at least one amplifier comprises at least one of a pre-driver amplifier (DA), a DA, or a power amplifier (PA), wherein the at least one bias current comprises at least one of a first bias current for the pre-DA, a second bias current for the DA, or a third bias current for the PA.

Aspect 12: The method according to any of Aspects 1-11, wherein the performance indicator comprises an adjacent channel leakage ratio (ACLR), an error vector magnitude (EVM), emissions, or sensitivity.

Aspect 13: An apparatus for signal amplification, comprising: at least one amplifier amplifying a signal; a controller coupled to the amplifier and configured to: cause a first adjustment of at least one bias current for the at least one amplifier; identify a performance indicator associated with the at least one amplifier after the first adjustment of the at least one bias current; and cause a second adjustment of the bias current for the at least one amplifier based on the performance indicator.

Aspect 14: The apparatus of Aspect 13, wherein the controller is configured to cause the first adjustment while the apparatus is operating in mission mode.

Aspect 15: The apparatus of Aspect 13 or 14, wherein, to cause the first adjustment of the at least one bias current, the controller is configured to cause the bias current for the at least one amplifier to decrease.

Aspect 16: The apparatus according to any of Aspects 13-15, wherein the controller is configured to cause the second adjustment based on the performance indicator meeting a performance indicator threshold.

Aspect 17: The apparatus of Aspect 16, wherein, to cause the first adjustment, the controller is configured to cause the at least one bias current for the at least one amplifier to decrease, and wherein, to cause the second adjustment, the controller is configured to cause the bias current for the at least one amplifier to further decrease based on the performance indicator meeting the performance indicator threshold.

Aspect 18: The apparatus according to any of Aspects 13-17, wherein, to cause the second adjustment, the controller is configured to set the bias current to at least one predetermined bias current level based on the performance indicator not meeting a performance indicator threshold.

Aspect 19: The apparatus of Aspect 18, wherein the at least one predetermined bias current level is determined to result in the performance indicator meeting the performance indicator threshold.

Aspect 20: A non-transitory computer-readable medium having instructions stored thereon, that when executed by one or more processors, cause the one or more processors to: cause a first adjustment of at least one bias current for at least one amplifier; identify a performance indicator associated with the at least one amplifier after the first adjustment of the at least one bias current; and cause a second adjustment of the bias current for the at least one amplifier based on the performance indicator.

Aspect 21: An apparatus for signal amplification, comprising: means for amplifying a signal; means for performing a first adjustment of at least one bias current for the means for amplifying; means for identifying a performance indicator associated with the means for amplifying after performing the first adjustment of the at least one bias current; and means for performing a second adjustment of the bias current for the at least one amplifier based on the performance indicator.

### ADDITIONAL CONSIDERATIONS

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.” For example, means for amplifying may include at least one amplifier such as the DA 314, PA 316, PA 410, transistor 708 (e.g., forming a DA), and/or transistor 718 (e.g., forming a PA). Means for performing may include a controller such as the RF controller 402, and/or a bias circuit such as the DA bias circuit 704 or the PA bias circuit 716. Means for identifying may include a modem (or any suitable processor(s)) such as the modem 404.

It is to be understood that the claims are not limited to the precise configuration and components illustrated above. Various modifications, changes and variations may be made in the arrangement, operation and details of the methods and apparatus described above without departing from the scope of the claims.

1. A method for signal amplification, comprising:
amplifying a signal via at least one amplifier;
performing a first adjustment of at least one bias current for the at least one amplifier;
performing, after the first adjustment, one or more configuration adjustments associated with the at least one amplifier to improve a performance indicator;
identifying the performance indicator associated with the at least one amplifier after performing the first adjustment of the at least one bias current and after performing the one or more configuration adjustments; and
performing a second adjustment of the at least one bias current for the at least one amplifier based on the performance indicator.

2. The method of claim 1, wherein the first adjustment is performed while the at least one amplifier is operating in mission mode.

3. The method of claim 1, wherein performing the first adjustment of the at least one bias current comprises decreasing the at least one bias current for the at least one amplifier.

4. The method of claim 1, wherein the second adjustment is performed based on the performance indicator meeting a performance indicator threshold.

5. The method of claim 4, wherein performing the first adjustment comprises decreasing the at least one bias current for the at least one amplifier, and wherein performing the second adjustment comprises further decreasing the at least one bias current for the at least one amplifier based on the performance indicator meeting the performance indicator threshold.

6. The method of claim 1, wherein performing the second adjustment comprises setting the at least one bias current to at least one predetermined bias current level based on the performance indicator not meeting a performance indicator threshold.

7. The method of claim 6, wherein the at least one predetermined bias current level is determined to result in the performance indicator meeting the performance indicator threshold.

8. (canceled)

9. The method of claim 1, wherein performing the one or more configuration adjustments includes at least one of adjusting a digital predistortion of the signal to be amplified or adjusting an input power associated with the signal to be amplified.

10. The method of claim 1, further comprising detecting whether the at least one bias current after performing the first adjustment has reached at least one bias current threshold, wherein the second adjustment of the at least one bias current is performed based on the detection.

11. The method of claim 1, wherein the at least one amplifier comprises at least one of a pre-driver amplifier (DA), a DA, or a power amplifier (PA), wherein the at least one bias current comprises at least one of a first bias current for the pre-DA, a second bias current for the DA, or a third bias current for the PA.

12. The method of claim 1, wherein the performance indicator comprises an adjacent channel leakage ratio (ACLR), an error vector magnitude (EVM), emissions, or sensitivity.

13. An apparatus for signal amplification, comprising:
at least one amplifier amplifying a signal;
a controller coupled to the amplifier and configured to:
cause a first adjustment of at least one bias current for the at least one amplifier;
perform, after the first adjustment, one or more configuration adjustments associated with the at least one amplifier to improve a performance indicator;
identify the performance indicator associated with the at least one amplifier after the first adjustment of the at least one bias current and after performing the one or more configuration adjustments; and
cause a second adjustment of the at least one bias current for the at least one amplifier based on the performance indicator.

14. The apparatus of claim 13, wherein the controller is configured to cause the first adjustment while the apparatus is operating in mission mode.

15. The apparatus of claim 13, wherein, to cause the first adjustment of the at least one bias current, the controller is configured to cause the at least one bias current for the at least one amplifier to decrease.

16. The apparatus of claim 13, wherein the controller is configured to cause the second adjustment based on the performance indicator meeting a performance indicator threshold.

17. The apparatus of claim 16, wherein, to cause the first adjustment, the controller is configured to cause the at least one bias current for the at least one amplifier to decrease, and wherein, to cause the second adjustment, the controller is configured to cause the at least one bias current for the at least one amplifier to further decrease based on the performance indicator meeting the performance indicator threshold.

18. The apparatus of claim 13, wherein, to cause the second adjustment, the controller is configured to set the at least one bias current to at least one predetermined bias current level based on the performance indicator not meeting a performance indicator threshold.

19. The apparatus of claim 18, wherein the at least one predetermined bias current level is determined to result in the performance indicator meeting the performance indicator threshold.

20. A non-transitory computer-readable medium having instructions stored thereon, that when executed by one or more processors, cause the one or more processors to:
cause a first adjustment of at least one bias current for at least one amplifier;
perform, after the first adjustment, one or more configuration adjustments associated with the at least one amplifier to improve a performance indicator;
identify the performance indicator associated with the at least one amplifier after the first adjustment of the at least one bias current and after performing the one or more configuration adjustments; and
cause a second adjustment of the at least one bias current for the at least one amplifier based on the performance indicator.
